(19) United States
(12) Patent Application Publication
(10) Pub. No.: US 2015/0189781 A1
(43) Pub. Date: Jul. 2, 2015

(54) MULTI-POSITION STAND FOR ELECTRONIC DISPLAY DEVICES

(71) Applicant: Zvi Klepar, New York, NY (US)

(72) Inventor: Zvi Klepar, New York, NY (US)

(21) Appl. No.: 14/142,352

(22) Filed: Dec. 27, 2013

(51) Int. Cl. H05K 5/03; H05K 5/02

(52) U.S. Cl. CPC H05K 5/03; H05K 5/0234; H05K 5/023

(57) ABSTRACT

The present invention is a multi-position stand for supporting an electronic display device in one or more usage configurations and comprises: a first receiving panel configured to support the electronic display; a second receiving panel attached to the first receiving panel, the second receiving panel configured to support a second electronic display; and a base panel attached to the first receiving panel and to the second receiving panel to form a substantially triangular cylinder with a hand access opening within the multi-position stand.

### FIELD OF THE INVENTION

The present disclosure is generally related to a stand that can support various types of electronic display devices. More particularly, the present invention pertains to a multi-position stand for portable electronic display devices, such as tablet computers, that can enhance comfort level for the user of the tablet computer.

### BACKGROUND OF THE INVENTION

Stands especially designed for tablet computers are well-known in the relevant art. Such stands have a limitation of being able to be used only while a user is seated or standing near a table. Most such conventional stands have provision for holding and viewing the tablet computers or like devices in desired angle. However, in most of such stands the receiving portions that hold the tablet are slidable. They are mainly meant to provide different inclination to the tablet computer for comfort in viewing.

Today, almost all kinds of tablet computers or like devices operate through the user's fingers by way of a touch sensitive display. The users operate the device with one hand while supporting the device with the other hand. During extended use in various locations (such as at home, in the office, or during travel), which locations are not specifically configured for operation of such devices, use of the tablet computer can create discomfort for the user. In order to overcome this discomfort, the user may rest the tablet device on a flat surface. However, the tablet device may still need to be gripped with one hand so as to maintain desired viewing angle.

In an effort to reduce this discomfort associated with operation of the devices in various locations, a number of computer stands have been devised or designed in the past. One such stand is discussed in U.S. Published Application No. 2013/0119225. Application '225 discloses a stand that supports tablet computers or like devices. The stand allows the user to adjust the tablet computer at a user defined orientation relative to a support surface and maintain the device at the defined orientation. The stand has an engagement portion and a support portion. The support portion of the stand includes a deformable mass conforming substantially to a smooth support surface in order to allow adjustment of the inclination of the display device to a desired inclination. However in such devices, in order to achieve the desired orientation, the user has to apply deformation force to the support portion or the deformable mass or the tablet computer engaged therein.

Therefore there is a need for a multi-position stand for portable electronic display devices such as tablet computers that can securely hold the tablet computer during its use and provide enhances comfort of using the tablet computer at various locations.

An object of the present invention is to provide an improved, easy to use and cost effective stand for electronic display devices, such as tablet computers, that helps retain the tablet in its position in a more secured manner such as to protect the device against breakage during accidental fall.

Another object of the present invention is to provide a more satisfactory solution that replaces conventional regular tablet stands designed for holding the tablet computers.

A further object of the present invention is to provide a stand for tablet computers. or like electronic display devices with a hand access opening within the stand that includes a finger grip to provide comfort to the user such that the user can easily flip over the multi-position stand in one or more usage configurations.

Another object of the present invention is to provide a multi-position stand for tablet computers or like electronic display devices that helps maintain consistency in holding, positioning and retrieving of the tablet computers in and out of the stand.

Yet another object of the present invention is to help users quickly change the viewing angle and orientation of the tablet computers in one of several positions without having to apply any force or make any technical changes to the stand holding the tablet device.

A further object of the present invention is to provide a multi-position stand suitably designed and sized to be locatable on a user's lap, thigh, or any other surfaces at home or at work stations enabling easy and extended use of the tablet computers in various locations.

### BRIEF SUMMARY OF THE INVENTION

In one aspect of the present invention, a multi-position stand suitable for supporting an electronic display device in one or more usage configurations comprises: a first receiving panel configured to support the electronic display; a second receiving panel attached to the first receiving panel, the second receiving panel configured to support a second electronic display; and a base panel attached to the first receiving panel and to the second receiving panel, the base panel forming a structure with the first receiving panel and the second receiving panel, the structure having the shape of a substantially triangular cylinder to define a hand access opening within the multi-position stand; wherein the multi-position stand is configured for use in more than one orientation.

In another aspect of the present invention, a multi-position stand suitable for supporting electronic display devices in one or more usage configurations comprises: a first receiving panel having an L-channel configured to support a first electronic display; a second receiving panel attached to the first receiving panel, the second receiving panel having a support channel configured to support a second electronic display; and a base panel attached to the first receiving panel and to the second receiving panel, the base panel forming a structure with the first receiving panel and the second receiving panel, the structure having the shape of a substantially triangular cylinder to define a hand access opening within the multi-position stand, the hand access opening having a ribbed finger grip extending along an inside surface of the first receiving panel and along an inside surface of the second receiving panel.

In still another aspect of the present invention, a method of supporting electronic display devices in one or more usage configurations comprises: providing a first receiving panel having an L-channel configured to support a first electronic display; attaching a second receiving panel to the first receiving panel, the second receiving panel having a support channel configured to support a second electronic display; attaching one end of a base panel to the first receiving panel, and a second end of the base panel to the second receiving panel, the base panel forming a multi-position stand with the first receiving panel and the second receiving panel, the multi-position stand having a substantially open triangular cylindrical shape; and emplacing the electronic device against the multi-position stand so as to engage at least one of the L-channel and the support channel.

The additional features and advantage of the disclosed invention is set forth in the detailed description which follows, and will be apparent to those skilled in the art from the description or recognized by practicing the invention as described, together with the claims and appended drawings.

### BRIEF DESCRIPTIONS OF THE DRAWINGS

The present invention will become fully appreciated as the same becomes better understood when considered in conjunction with the accompanying drawings, and wherein:

FIG. 1 shows a perspective view of a multi-position stand, according to the present invention;

FIG. 2 shows a computer display device supported by the multi-position stand of FIG. 1;

FIG. 3 shows an alternative computer display device supported in a portrait orientation by the multi-position stand of FIG. 1;

FIG. 4 shows the alternative computer display device of FIG. 3 supported in a landscape orientation;

FIG. 5 shows a user hand inserted into a hand access opening to hold the multi-position stand of FIG. 1;

FIG. 6 shows the computer display device of FIG. 1 supported by the multi-position stand in a different orientation;

FIG. 7 shows a user supporting the computer display device of FIG. 1 in a lap orientation;

FIG. 8 shows the computer display device of FIG. 1 supporting a tablet computer with a tablet case; and

FIG. 9 shows the tablet computer case of FIG. 8 extending from a receiving panel of the computer display device of FIG. 1.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention.

Before explaining at least one embodiment of the present invention in detail, it is to be understood that the invention is not limited in its application to the details of construction or to the arrangements of elements in the following description or illustrated in the drawings. The invention is capable of other embodiments and of being practiced and carried out in various ways. Also, it is to be understood that the phraseology and terminology employed herein are for the purpose of the description and should not be regarded as limiting.

The proposed multi-position stand is designed for electronic display devices, such as tablet computers including but not limited to iPad® from Apple, Xoom® from Motorola, Galaxy from Samsung, and Amazon Kindle®. Even some new smart phones acting like small tablet computers can also be used. What is required is just an adjustment in the size of the stand as will be appreciated by those skilled in the art. Generally, the problem with tablet computers is that they are flat and must typically be held with one or both hands for comfortable use or to view in desired angle. The interface of tablets is normally through the touch screen. The simplicity of tablet computers allows them to be used in ways that laptop and desktop computers cannot be used. The tablet computers can be used as an e-reader to read newspapers, magazines or various articles. The tablet computers can further be used for watching movies or TV in bed, or for surfing the Internet while sitting or lying down on a sofa or bed or in an easy chair.

Exemplary embodiment of the present invention is directed towards a multi-position stand for securely holding an electronic display device, such as tablet computers, in one or more usage configurations accessible by: (i) flipping the stand relative to a user, or (ii) using the stand in substantially flat position, or (iii) using the stand as vertical or horizontal stand. The user is enabled to flip over the stand holding the tablet computer in one of three ‘flip’ positions to get a specific viewing angle or use the tablet as a simple stand preferably like the e-reader. The user as desired can place the tablet computer in the stand either in portrait or landscape orientation.

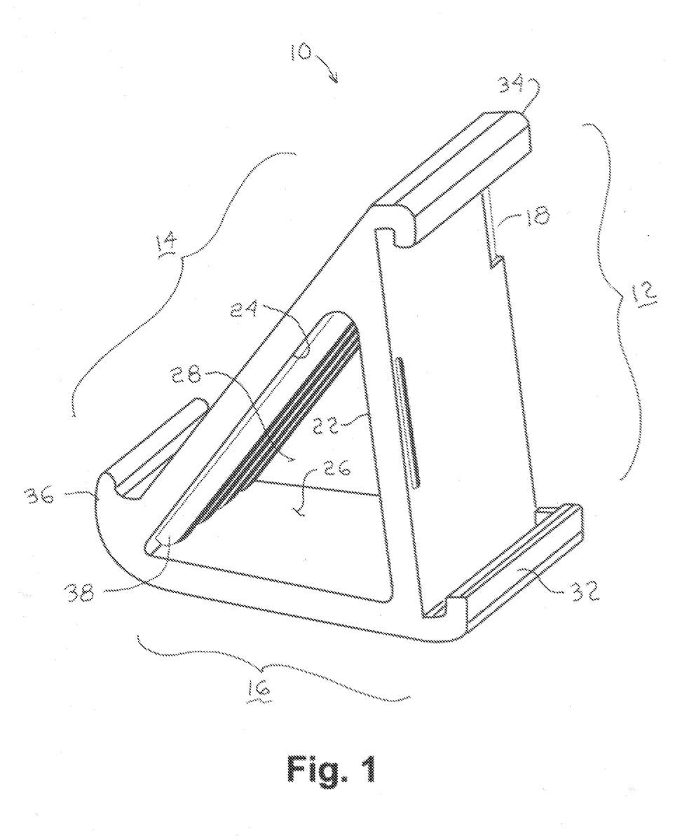

According to an embodiment of the present invention, a multi-position stand 10 is disclosed, the multi-position stand 10 being configured for securely holding an electronic display device, such as a tablet computer, in either a portrait orientation or a landscape orientation. The multi-position stand 10 includes a first receiving panel 12, a second receiving panel 14, and a base panel 16, as shown in FIG. 1. The surface of the first receiving panel 12 may include a recess 18 to allow the user to grasp the electronic display device when desired. In an exemplary embodiment, the multi-position stand 10 may be fabricated from versatile, lightweight and inexpensive materials, such as, but not limited to, ethylene vinyl acetate (EVA), or similar plastic or rubber material.

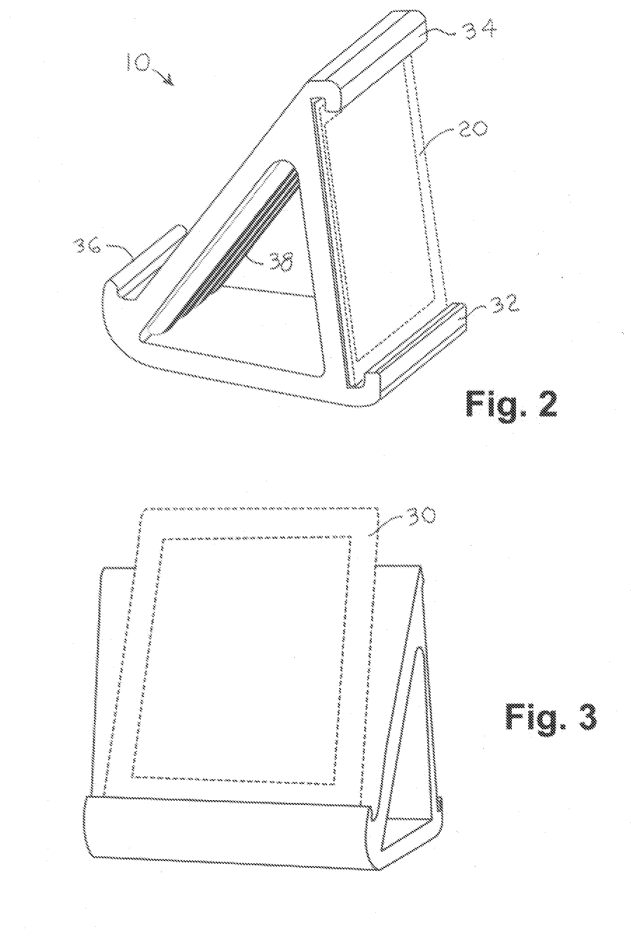

Each of the first receiving panel 12, the second receiving panel 14, and the base panel 16 comprise substantially rectangular and planar surfaces, and are interconnected to form a structure having the shape of an open, substantially triangular cylinder with a hand access opening 28 at either end of the open triangular cylinder. The hand access opening 28 is bounded by an inside surface 22 of the first receiving panel 12, an inside surface 24 of the second receiving panel 14, and an inside surface 26 of the base panel 16. The first receiving panel 12 and the second receiving panel 14 are dimensioned and oriented with respect to one another such that the multi-position stand 10 is shaped and angled to maintain a first electronic display device 20 at a comfortable angle relative to the body and line of vision of the user, as shown in FIG. 2.

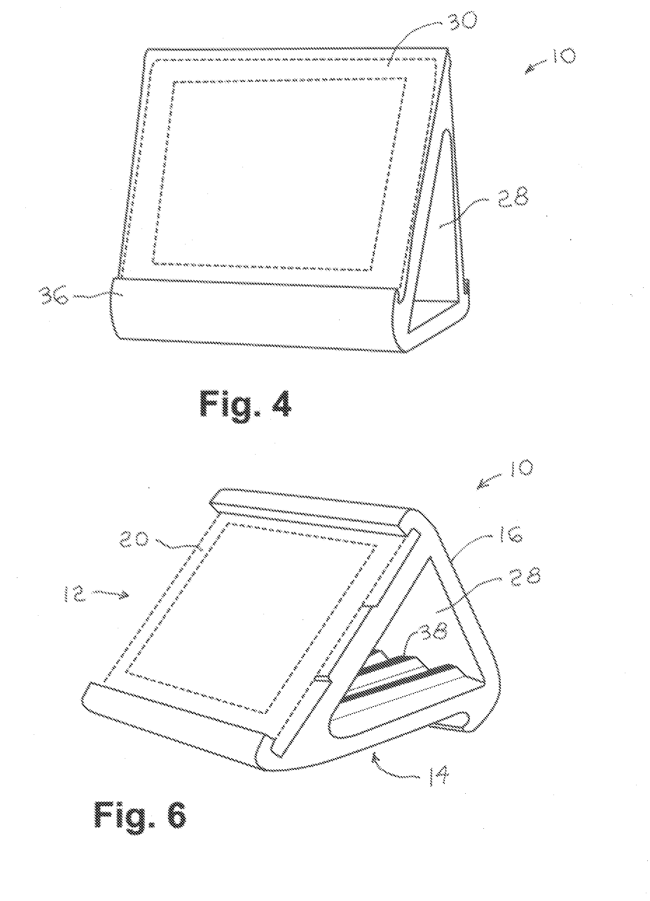

As seen in FIGS. 1 and 2, the first receiving panel 12 includes a first L-channel 32 and a second L-channel 34 disposed on two opposing sides of the first receiving panel 12, for securely holding the first electronic display device 20. It can be appreciated by one skilled in the art that the first L-channel 32 is separated from the second L-channel 34 by a dimension approximately the same as a width or length of the first electronic display device 20. The first electronic display device 20 may then be emplaced so as to engage either or both the first L-channel 32 and the second L-channel 34. The second receiving panel 14 includes a support channel 36 disposed on one side of the second receiving panel 14 and configured to provide support to a second electronic display device 30, shown in FIGS. 3 in portrait orientation, and in FIG. 4 in landscape orientation. Accordingly, the base panel 16 extends between, and is connected to both, the first L-channel 32 and the support channel 36.

It can be appreciated by one skilled in the art that one or both of the length and the width of the second electronic display device 30 may be greater than either the length and width of the first electronic display device 20 and, as such, the dimensions of the second electronic display 30 might not allow for emplacement of the second electronic display device 30 within the confines of the first receiving panel 12, that is, placed between the first L-channel 32 and the second L-channel 34 and against the first receiving panel 12. Accordingly, the user may place the second electronic device 30 against the second receiving panel 14, as shown in FIGS. 3 and 4, so as to engage the support channel 36. In addition, the first electronic display device 20 may be used as an e-reader when placed against the second receiving panel 14.

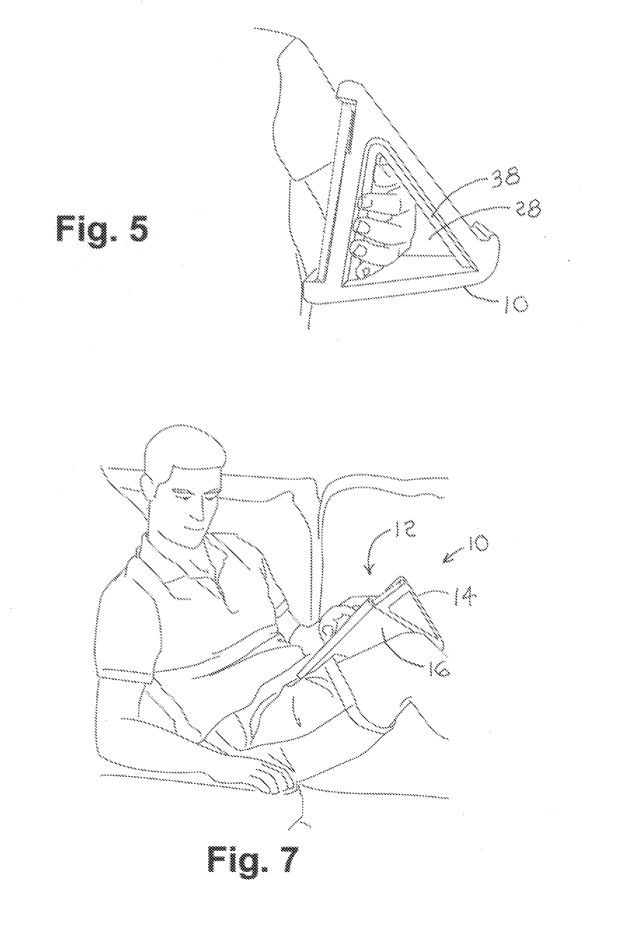

In an exemplary embodiment, the hand access opening 28 may include a ribbed finger grip 38, shown in FIGS. 1 and 2, extending along the inside surface 22 and the inside surface 24 to provide comfort to the user when grasping the multi-position stand 10. The ribbed finger grip 38 enables the user to carry or to flip over the multi-position stand 10 by using only one hand, as best seen in FIG. 5.

FIG. 6 shows the multi-position stand 10 as may be used in an alternative orientation. As shown in the illustration, the electronic display device 20 is supported on the first receiving panel 12, the second receiving panel 14 faces downward, and the base panel 16 faces away from the user. As can be appreciated by one skilled in the art, the multi-position stand 10 can be used in any of the three positions shown in FIGS. 2, 4, and 6.

In an alternative embodiment, shown in FIG. 7, the multi-position stand 10 may be placed between the knees of the user, allowing the electronic display device 20 to rest on the first receiving panel 12, with each of the second receiving panel 14 and the base panel 16 resting in a user lap against a respective user's knee. In this particular orientation, the electronic display device 20 presents the display screen at a normal (i.e., perpendicular) orientation to the user.

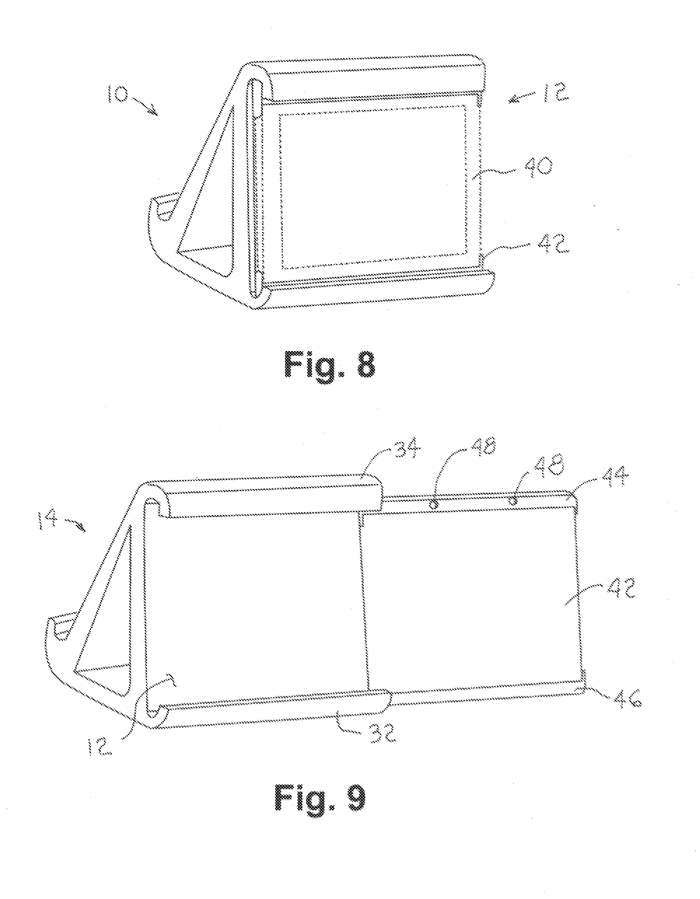

According to an exemplary embodiment, shown in FIG. 8, the multi-position stand 10 can also be used to hold a tablet computer 40 having a tablet case 42 as is commonly available in the market for various tablet computers. Accordingly, the tablet computer 40 and the tablet case 42 may both be emplaced in the first receiving panel 12, as shown in FIG. 8. Alternatively, the tablet case 42 may be left in the first receiving panel 12, and the tablet computer 40 may be placed in the second receiving panel 14, as indicated in FIG. 9.

The tablet case 42 may also include a pair of retaining channels 44, 46 that frictionally engage with the first L-channel 32 and the second L-channel 34 provided at the top edge and at the bottom edge of the first receiving panel 12. The tablet case 42 is preferably designed so as to hold various present state of the art Android display devices including, for example, the recently-launched iPad Air that presents smaller dimensions than an earlier generation mobile communication and display device (not shown).

According to this embodiment, the tablet case 42 may itself be used as a standalone holder for the users of such Android devices, or for holding various smart phones, and the like, upon removal from the multi-position stand 10. Further, the tablet case 42 may comprise one or more specifically angulated holes 48 at the retaining channels 44, 46, shown in FIG. 9. The user can place a rod-like component, such as a pencil, into the holes 48 to enable the mobile electronic display device, such as an Android device, to hold the device at a specified, substantially vertical angle, when resting on a support surface.

As can be appreciated by one skilled in the art, the present invention focuses on the capability to provide different usage configurations of the disclosed multi-position stand, and the secure holding configuration for a tablet computer which is not found in conventional tablet stands. The development of the proposed multi-position stand and its properties help meet the objectives and advantageous features of the invention discussed in aforementioned summary and detailed description.

It should be understood that the design of the multi-position stand is not limited in the size and material used for its construction as discussed above, and the structure may be manufactured in varying sizes using varying material as per requirement. However, it is to be understood that the increase in size and choice of better material increases the cost of manufacturing. It is further to be understood that, although the disclosed multi-position stand is described above with reference to tablet computers and similar devices, it will be appreciated that the stand is not limited to this particular field of use and may be used to hold any other type of display devices without departing from the spirit and scope of the present invention.

It is to be further understood that the description herein is only exemplary of the invention, and is intended to provide an overview for the understanding of the nature and character of the disclosed multi-position stand. The accompanying drawings are included to provide a further understanding of various features and embodiments of the method and devices of the invention which, together with their description serve to explain the principles and operation of the invention.

What is claimed is:

1. A multi-position stand suitable for supporting an electronic display device in one or more usage configurations, said stand comprising:
a first receiving panel configured to support the electronic display;
a second receiving panel attached to said first receiving panel, said second receiving panel configured to support a second electronic display; and
a base panel attached to said first receiving panel and to said second receiving panel, said base panel forming a structure with said first receiving panel and said second receiving panel, said structure having the shape of a substantially triangular cylinder to define a hand access opening within said multi-position stand;
wherein said multi-position stand is configured for use in more than one orientation.

2. The multi-position stand of claim 1 further comprising a first L-channel and a second L-channel attached to said first receiving panel.

3. The multi-position stand of claim 1 further comprising a support channel attached to said second receiving panel.

4. The multi-position stand of claim 1 further comprising a ribbed finger grip extending along an inside surface of said first receiving panel.

5. The multi-position stand of claim 1 wherein a surface of said first receiving panel comprises a recess to provide for grasping the electronic display device.

6. The multi-position stand of claim 1 wherein said first receiving panel comprises a material from the group consisting of: ethylene vinyl acetate, a plastic, or a rubber material.

7. The multi-position stand of claim 1 wherein said first receiving panel comprises a substantially planar, rectangular surface.

8. A multi-position stand suitable for supporting electronic display devices in one or more usage configurations, said stand comprising:
a first receiving panel having an L-channel configured to support a first electronic display;
a second receiving panel attached to said first receiving panel, said second receiving panel having a support channel configured to support a second electronic display; and
a base panel attached to said first receiving panel and to said second receiving panel, said base panel forming a structure with said first receiving panel and said second receiving panel, said structure having the shape of a substantially triangular cylinder to define a hand access opening within said multi-position stand, said hand access opening having a ribbed finger grip extending along an inside surface of said first receiving panel and along an inside surface of said second receiving panel.

9. The multi-position stand of claim 8 wherein said second receiving panel comprises a substantially planar, rectangular surface.

10. The multi-position stand of claim 8 wherein said base panel extends between said L-channel and said support channel.

11. A method of supporting electronic display devices in one or more usage configurations, said method comprising the steps of:
providing a first receiving panel having an L-channel configured to support a first electronic display;
attaching a second receiving panel to said first receiving panel, said second receiving panel having a support channel configured to support a second electronic display;
attaching one end of a base panel to said first receiving panel, and a second end of said base panel to said second receiving panel, said base panel forming a multi-position stand with said first receiving panel and said second receiving panel, said multi-position stand having a substantially open triangular cylindrical shape; and
emplacing the electronic device against said multi-position stand so as to engage at least one of said L-channel and said support channel.

12. The method of claim 11 further comprising the step of inserting a user hand into said multi-position stand so as to grasp a ribbed finger grip extending along an inside surface of said first receiving panel.

13. The method of claim 11 wherein at least one of said first receiving panel, said second receiving panel, and said base panel comprises a material from the group consisting of:
ethylene vinyl acetate, a plastic, or a rubber material.
